(19) United States
(12) Patent Application Publication
(10) Pub. No.: US 2022/0026787 A1
(43) Pub. Date: Jan. 27, 2022

(54) PROJECTOR COOLING SYSTEM

(71) Applicant: Coretronic Corporation, Hsin-Chu (TW)

(72) Inventors: Yi-Han Lai, Hsin-Chu (TW); Shi-Wen Lin, Hsin-Chu (TW); Tsung-Ching Lin, Hsin-Chu (TW)

(73) Assignee: Coretronic Corporation, Hsin-Chu (TW)

(21) Appl. No.: 17/316,730

(22) Filed: May 11, 2021

(30) Foreign Application Priority Data
Jul. 22, 2020 (CN) 202021452375.9

(51) Int. Cl. G03B 21/16; H05K 7/20

(52) U.S. Cl. CPC G03B 21/16; H05K 7/2039

(57) ABSTRACT

A projector cooling system, including a casing, a first heat generating component, and a second heat generating component, is provided. The first heat generating component and the second heat generating component are sequentially disposed in the casing along an anti-gravity direction. A temperature of the first heat generating component is lower than a temperature of the second heat generating component. The projector cooling system of the invention is adapted to introduce more cooling airflow without using a moving part, thereby reducing the temperatures of the heat generating components.

### CROSS-REFERENCE TO RELATED APPLICATION

This application claims the priority benefit of China application serial no. 202021452375.9, filed on Jul. 22, 2020. The entirety of the above-mentioned patent application is hereby incorporated by reference herein and made a part of this specification.

### BACKGROUND

### Technical Field

The invention relates to a cooling system, and particularly relates to a projector cooling system.

### Description of Related Art

Cooling of electronic component is very important, since the service life and performance of the electronic component are highly related to temperature. Generally, the lower the temperature of the electronic component is, the longer the service life is and the better the performance is. A cooling design is mainly divided into active cooling and passive cooling, and a difference there between lies in whether a moving part is used to enhance an airflow rate of a cooling airflow. The active cooling usually uses a fan as the moving part to enhance the airflow rate. However, when the moving part is used, some problems related to engineering reliability such as noise, vibration, a fatigue life, etc., are increased. Therefore, how to enhance the airflow rate to improve the cooling efficiency without using the moving part has become one of the important issues of passive cooling.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The invention is directed to a projector cooling system, which is adapted to introduce more cooling air flow without using a moving part, so as to reduce a temperature of a heat generating component.

In order to achieve one or a portion of or all of the objects or other objects, an embodiment of the invention provides a projector cooling system including a casing, a first heat generating component and a second heat generating component. The first heat generating component and the second heat generating component are sequentially disposed in the casing along an anti-gravity direction. A temperature of the first heat generating component is lower than a temperature of the second heat generating component.

Based on the above description, the embodiment of the invention has at least one of following advantages or effects. In the design of the projector cooling system of the invention, the first heat generating component and the second heat generating component are sequentially disposed in the casing along the anti-gravity direction, and the temperature of the first heat generating component is lower than the temperature of the second heat generating component. In this way, the air in the casing is heated to generate an upward airflow, and more cooling airflow (i.e., airflow rate) is introduced to cool the first heat generating component. In brief, the projector cooling system of the invention utilizes a chimney effect to introduce more cooling airflow without using a moving part, thereby reducing the temperature of the heat source, and achieving a better cooling effect.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a three-dimensional (3D) schematic view of a projector cooling system according to an embodiment of the invention.

FIG. 1B is a 3D exploded schematic view of the projector cooling system of FIG. 1A.

FIG. 1C is a partial 3D cross-sectional schematic view of the projector cooling system of FIG. 1A.

FIG. 2 is a schematically perspective view of a projector cooling system in a casing according to another embodiment of the invention.

FIG. 3 is a schematically perspective view of a projector cooling system in a casing according to another embodiment of the invention.

FIG. 4 is a schematically perspective view of a projector cooling system in a casing according to another embodiment of the invention.

FIG. 5 is a schematically perspective view of a projector cooling system in a casing according to another embodiment of the invention.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

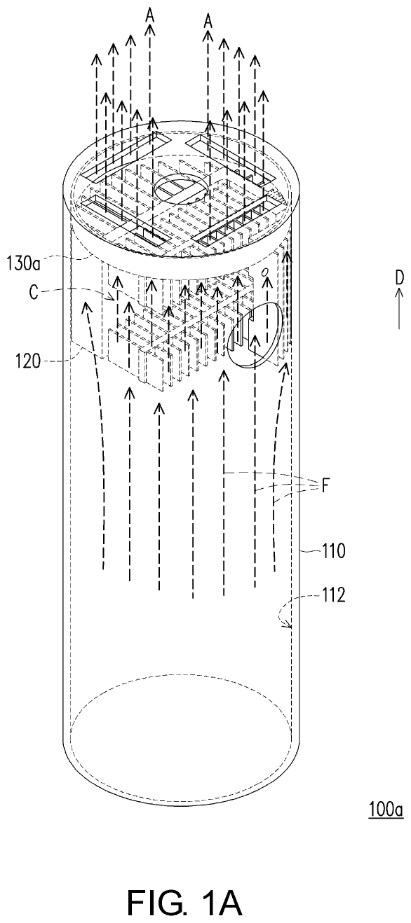

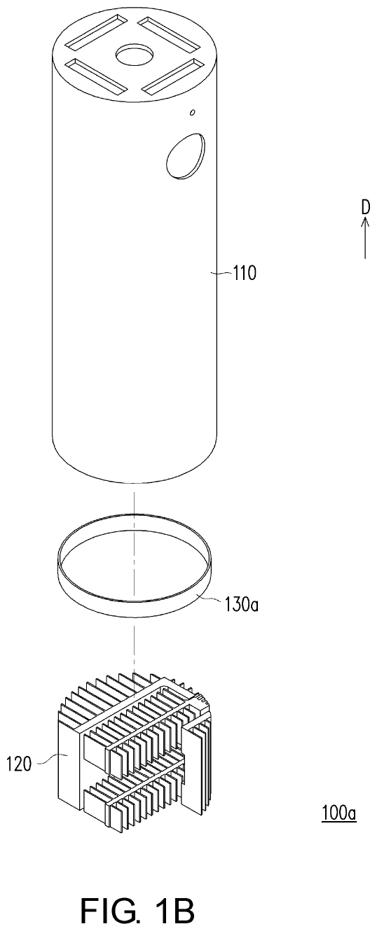

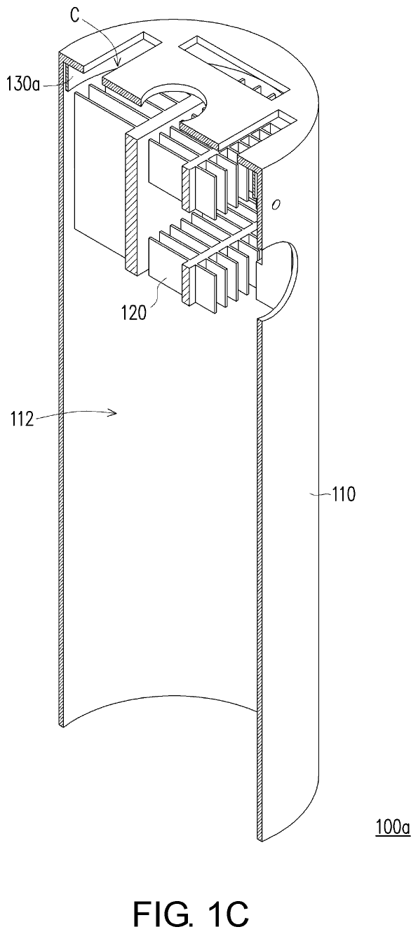

FIG. 1A is a three-dimensional (3D) schematic view of a projector cooling system according to an embodiment of the invention. FIG. 1B is a 3D exploded schematic view of the projector cooling system of FIG. 1A. FIG. 1C is a partial 3D cross-sectional schematic view of the projector cooling system of FIG. 1A.

Referring to FIG. 1A, FIG. 1B and FIG. 1C, in the embodiment, the projector cooling system 100a includes a casing 110, a first heat generating component 120 and a second heat generating component 130a. The first heat generating component 120 and the second heat generating component 130a are sequentially disposed in the casing 110 along an anti-gravity direction D. Particularly, a temperature of the first heat generating component 120 is lower than a temperature of the second heat generating component 130a. Namely, the second heat generating component 130a with the higher temperature is located above the first heat generating component 120 with the lower temperature.

To be specific, the casing 110 of the embodiment has an annular accommodating space 112, and the first heat generating component 120 and the second heat generating component 130a are located in the annular accommodating space 112. In particular, no fan is arranged in the casing 110 of the embodiment, which means that there is no moving part that may produce an airflow in the casing 110.

Moreover, the first heat generating component 120 of the embodiment is, for example, at least one solid-state light source, a cooling element connected to the solid-state light source, at least one light valve, a cooling element connected to the light valve, or a combination of the above elements. The solid-state light source is, for example, a laser diode (LD) or a light emitting diode LED), but the invention is not limited thereto. The light valve is, for example, a reflective light modulator such as a liquid crystal on silicon panel (LCoS panel), a digital micro-mirror device (DMD), etc. In an embodiment, the light valve is, for example, a transmissive optical modulator such as a transparent liquid crystal panel, an electro-optical modulator, a magneto-optic modulator, an acousto-optic modulator (AOM), etc., but the pattern and the type of the light valve are not limited by the embodiment. The cooling element is, for example, a non-moving part such as a cooling fin, a heat pipe or a heat sink, etc., which is used to transfer heat generated by the solid-state light source or the light valve. The pattern and the type of the cooling element are not limited by the embodiment.

In addition, the second heat generating component 130a of the embodiment is disposed in the casing 110 in a ring shape (for example, a circle), where an air passage C is formed between the first heat generating component 120 and the second heat generating component 130a to generate air circulation. The second heat generating component 130a is, for example, at least one circuit board, at least one power supply chip, at least one heater or other heat source capable of generating a higher temperature, but the invention is not limited thereto. The heat generated by the second heat generating component 130a increases an air temperature in the casing 110 to produce an airflow A flowing along the anti-gravity direction D, so as to introduce a cooling airflow F from the outside of the casing 110 to the first heat generating component 120 for passive cooling. Due to the heating of the second heat generating component 130a, the air in the casing 110 expands and an air density thereof is reduced, so that buoyancy is increased, and since the heated air may rise in the anti-gravity direction D, the airflow A in the projector cooling system 100a is guided to external smoothly, so as to increase the cooling airflow F, which is the so-called chimney effect.

In brief, the projector cooling system 100a of the embodiment uses the second heat generating component 130a to increase the air temperature in the casing 110 without using the moving part, thereby generating the upward airflow A, so that more cooling airflow F may sequentially cool down the first heat generating component 120 and the second heat generating component 130a. Namely, the chimney effect is used to introduce more cooling airflow F, thereby reducing the temperatures of the first heat generating component 120 and the second heat generating component 130a to achieve a better cooling effect.

It should be noticed that reference numbers of the components and a part of contents of the aforementioned embodiment are also used in the following embodiment, where the same reference numbers denote the same or like components, and descriptions of the same technical contents are omitted. The aforementioned embodiment may be referred for descriptions of the omitted parts, and detailed descriptions thereof are not repeated in the following embodiment.

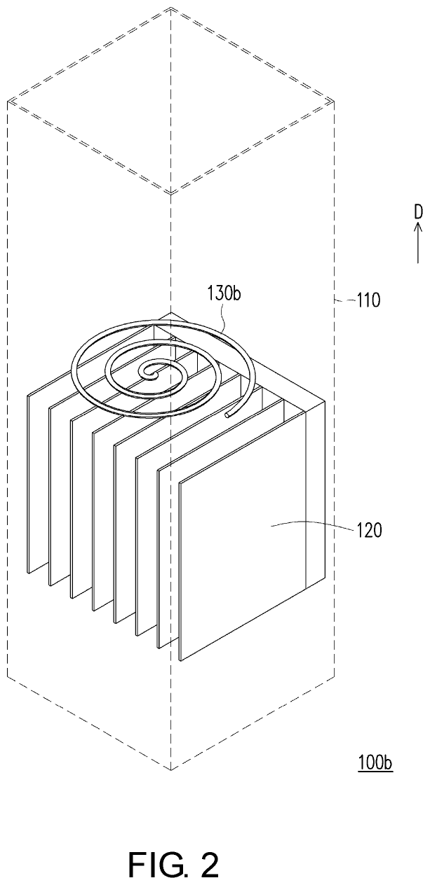

FIG. 2 is a schematically perspective view of a projector cooling system in a casing according to another embodiment of the invention. For the convenience of description, the casing 110 in FIG. 2 is indicated by dotted lines. Referring to FIG. 1B and FIG. 2 at the same time, a projector cooling system 100b of the embodiment is similar to the projector cooling system 100a of FIG. 1B, and a difference there between is that the second heat generating component 130b of the embodiment is a component with an outer contour of a spiral shape.

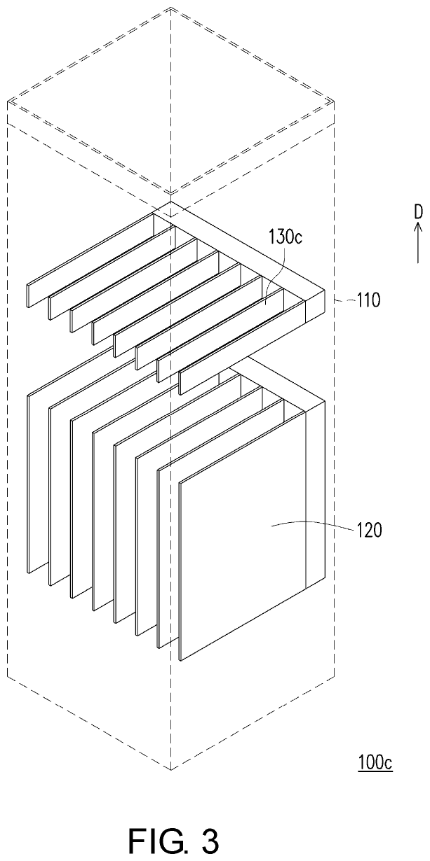

FIG. 3 is a schematically perspective view of a projector cooling system in a casing according to another embodiment of the invention. For the convenience of description, the casing 110 in FIG. 3 is indicated by dotted lines. Referring to FIG. 1B and FIG. 3 at the same time, a projector cooling system 100c of the embodiment is similar to the projector cooling system 100a of FIG. 1B, and a difference there between is that the second heat generating component 130c of the embodiment is a component with an outer contour of a fin shape.

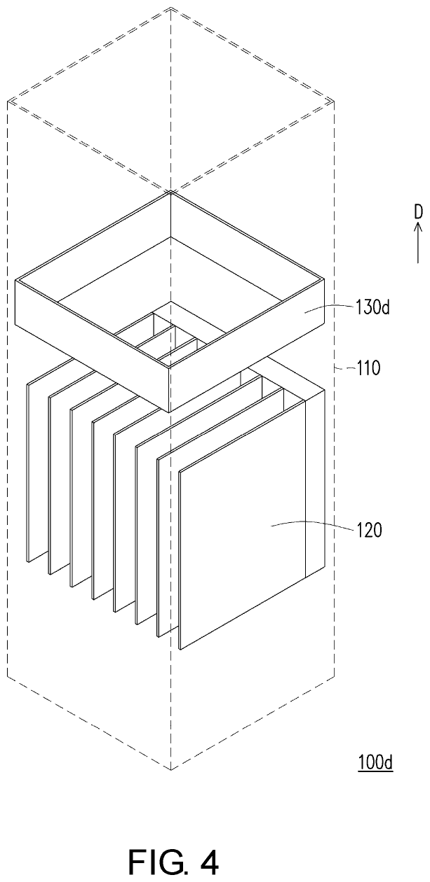

FIG. 4 is a schematically perspective view of a projector cooling system in a casing according to another embodiment of the invention. For the convenience of description, the casing 110 in FIG. 4 is indicated by dotted lines. Referring to FIG. 1B and FIG. 4 at the same time, a projector cooling system 100d of the embodiment is similar to the projector cooling system 100a of FIG. 1B, and a difference there between is that the second heat generating component 130d of the embodiment is a component with an outer contour of a rectangular shape.

As shown in FIG. 1A, FIG. 2, FIG. 3, and FIG. 4, the second heat generating components 130a, 130b, 130c, and 130d of different embodiments may all heat the air in the casings, and the outer contours of the second heat generating components 130a, 130b, 130c, and 130d of different embodiments all allow the introduced cooling airflow to pass through, thereby reducing the temperatures of the second heat generating components. In addition, the accommodating space of the casing 110 shown in FIG. 2, FIG. 3, or FIG. 4 may be rectangular, and is not limited to the ring shape, and the invention is not limited thereto. A following table 1 shows cooling effects of the first heat generating component 120 when the second heat generating component is not arranged and when the second heat generating component 130b, 130c, 130d with different contours are arranged in case that the first heat generating component 120 of the system has the same power (for example, 20 W).

TABLE 1

| | No second | Second heat | Second heat | Second heat |
|---|---|---|---|---|
| | heat | generating | generating | generating |
| | generating | component | component | component |
| System | component | 130b | 130c | 130d |
| Temperature of first | 54.7 | 54.5 (0.7%) | 54.1(2%) | 52.5(7.4%) |
| heat generating | | | | |
| component 120 (° C.) | | | | |
| Airflow rate (CFM) | 2.14 | 2.23(4.2%) | 2.36(10.3%) | 2.69(25.7%) |

According to the above table 1, it is clearly known that the second heat generating component 130d with the rectangular shape outer contour may reduce the temperature of the first heat generating component 120 most significantly, which may reduce the temperature of the first heat generating component 120 by 7.4%, and may introduce a system airflow rate of 25.7%.

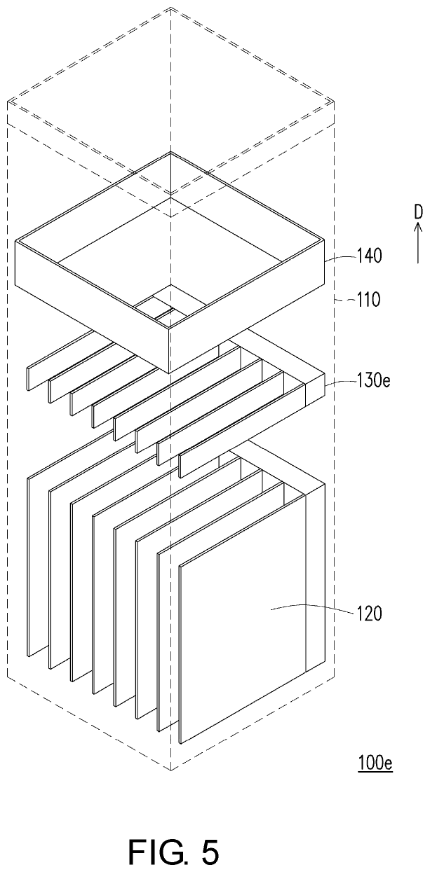

FIG. 5 is a schematically perspective view of a projector cooling system in a casing according to another embodiment of the invention. For the convenience of description, the casing 110 in FIG. 5 is indicated by dotted lines. Referring to FIG. 1B and FIG. 5 at the same time, a projector cooling system 100e of the embodiment is similar to the projector cooling system 100a of FIG. 1B, and a difference there between is that the projector cooling system 100e of the embodiment further includes a third heat generating component 140, where the third heat generating component 140 is disposed in the casing 110 and is located above the second heat generating component 130e along the anti-gravity direction D. The second heat generating component 130e is located between the third heat generating component 140 and the first heat generating component 120, and a temperature of the third heat generating component 140 is higher than the temperature of the second heat generating component 130e. Namely, the first heat generating component 120, the second heat generating component 130e, and the third heat generating component 140 are sequentially disposed along the anti-gravity direction D. The third heat generating component 140 is a heater, and the temperature of the first heat generating component 120 is controlled by adjusting the heater. Further, the higher the power of the third heat generating component 140 is, the more the cooling airflow F is introduced (referring to FIG. 1A). By monitoring the temperature of the first heat generating component 120, the power of the third heat generating component 140 may be adjusted to control the temperature of the first heat generating component 120 at a target temperature, so as to avoid wasting energy and achieve the most energy-efficient system operation. In an embodiment, the third heat generating component 140 may be combined with the casing 110 to save a system space of the projector cooling system 100e.

In summary, the embodiments of the invention have at least one of following advantages or effects. In the design of the projector cooling system of the invention, the first heat generating component and the second heat generating component are sequentially disposed in the casing along the anti-gravity direction, and the temperature of the first heat generating component is lower than the temperature of the second heat generating component. In this way, the air in the casing may be heated to generate an upward airflow, and more cooling airflow (i.e., airflow rate) is introduced to cool the first heat generating component. In brief, the projector cooling system of the invention utilizes the chimney effect to introduce more cooling airflow without using a moving part (for example, a fan), thereby reducing the temperature of the heat source, and achieving a better cooling effect.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A projector cooling system, comprising a casing, a first heat generating component, and a second heat generating component, wherein:
the first heat generating component and the second heat generating component are sequentially disposed in the casing along an anti-gravity direction; and
a temperature of the first heat generating component is lower than a temperature of the second heat generating component.

2. The projector cooling system as claimed in claim 1, wherein the first heat generating component comprises at least one solid-state light source, at least one light valve, or a combination thereof.

3. The projector cooling system as claimed in claim 1, wherein the second heat generating component comprises at least one circuit board, at least one power supply chip, or at least one heater.

4. The projector cooling system as claimed in claim 1, wherein an outer contour of the second heat generating component comprises a spiral shape, a fin shape, a rectangular shape, or a ring shape.

5. The projector cooling system as claimed in claim 1, further comprising:
a third heat generating component, disposed in the casing and located above the second heat generating component along the anti-gravity direction, wherein the second heat generating component is located between the third heat generating component and the first heat generating component, and a temperature of the third heat generating component is higher than the temperature of the second heat generating component.

6. The projector cooling system as claimed in claim 5, wherein the second heat generating component comprises at least one circuit board, at least one power supply chip, or a combination thereof, and the third heat generating component is a heater.

7. The projector cooling system as claimed in claim 5, wherein the third heat generating component is a heater, and the temperature of the first heat generating component is controlled by adjusting the heater.

8. The projector cooling system as claimed in claim 1, wherein heat generated by the second heat generating component increases an air temperature in the casing to generate an airflow flowing along the anti-gravity direction, so as to introduce a cooling airflow to the first heat generating component for passive cooling.

9. The projector cooling system as claimed in claim 8, wherein an air passage is formed between the first heat generating component and the second heat generating component to generate air circulation.

10. The projector cooling system as claimed in claim 1, wherein the casing has an annular accommodating space, and the first heat generating component and the second heat generating component are located in the annular accommodating space.

11. The projector cooling system as claimed in claim 1, wherein no fan is arranged in the casing.

12. The projector cooling system as claimed in claim 1, wherein the second heat generating component is disposed in the casing in a ring shape.
